(19) United States
(12) Patent Application Publication
(10) Pub. No.: US 2010/0200957 A1
(43) Pub. Date: Aug. 12, 2010

(54) Scribe-Line Through Silicon Vias

(75) Inventor: Arvind Chandrasekaran, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/366,846

(22) Filed: Feb. 6, 2009

(51) Int. Cl. H01L 29/06; H01L 21/784

(52) U.S. Cl. 257/618; 438/113; 257/E29.005; 257/E21.703

(57) ABSTRACT

A semiconductor wafer includes dies to be scored from the semiconductor wafer. The semiconductor wafer also includes scribe-lines between the dies. Each scribe-line includes multiple through silicon vias.

### TECHNICAL FIELD

The present disclosure generally relates to integrated circuits (ICs). More specifically, the present disclosure relates to manufacturing integrated circuits.

### BACKGROUND

Integrated circuits (ICs) are fabricated on wafers. Commonly, these wafers are semiconductor materials, and, in particular, silicon. As transistors on the ICs have reduced size in lateral dimensions over the years, the thickness of the wafer has generally not been proportionally reduced. Transistor behavior is dependent on the thickness of the wafer, but at current sizes of 45 nm, and soon 32 nm and smaller, the thickness of the wafer is larger than needed for operational transistor behavior.

Thicker wafers have advantages in the manufacturing process outside of transistor operational behavior. During fabrication of circuits and packaging of dies, the wafer endures dozens of processes, high temperatures, and dozens of transfers between tools or even fabrication sites. During these transfers the wafer can break, in which case a loss of time and resources occurs. Thicker wafers are less likely to break during fabrication; thinner wafers are a challenge to manufacture because of their fragility.

One part of the manufacturing process where mechanical stability is important is during scoring into individual dies. Commonly, saws are used to score the wafers into individual dies, but other methods such as laser scoring are available. In saw cutting, a blade coated with diamond or carbon grit rotating at several thousand revolutions per minute engages the wafer while the wafer is fed through the saw. The process is optimized through parameters including substrate material, substrate thickness, metals deposited on the substrate, rotation speed of the blade, and feed rate of the wafer.

Wafers are sensitive to the cutting process because the single crystal material of the wafer allows stress fractures to propagate quickly and without any significant additional forces. Additionally, chipping of the wafer can lead to later mechanical stability problems of the packaged product. One method used to reduce chipping is a step-cut process where a first pass of the blade cuts a fraction into the thickness of the wafer, and a second pass completes the cut.

Scribe-lines are built into wafers before the dies are manufactured to reduce the possible damage to the wafer during scoring. The scribe-lines are manufactured using semiconductor fabrication processes that do not result in any chipping. These scribe-lines are portions of the wafer that have been thinned and facilitate scoring of the die by providing a path for the blade and reducing the amount of material the blade must cut. As a result, occurrences of chipping are reduced and throughput of wafers through the saw is increased.

Recently, efforts have been made to use thinner wafers, while minimizing damage during fabrication. One of such techniques involves attaching the thin wafers for use in ICs to a carrier wafer with an adhesive during manufacturing. The carrier wafers are significantly thicker (300-1000 μm) than the thin wafers (30-300 μm) and act to provide stability during processing. The high temperatures experienced during fabrication of ICs, however is difficult for most adhesives to withstand. To prevent the thin wafer from detaching from the carrier wafer inadvertently, the adhesives are carefully designed to withstand temperatures higher than encountered during fabrication.

After processing for the thin wafer is completed, the carrier wafer is detached from the thin wafer. Although the carrier wafer provides stability during manufacturing, releasing the thin wafer from the carrier wafer represents an additional challenge.

Conventional methods to release the carrier wafer from the thin wafer include laser heating and bulk chemical etching. As a first example, if the carrier wafer is chosen to be transparent, a laser may be shown through the transparent carrier wafer to heat the adhesive between the carrier wafer and the thin wafer to a temperature at which the adhesive releases the thin wafer. This process is difficult to design because the temperature at which the adhesive releases the thin wafer from the carrier wafer should be higher than any temperature experienced during manufacturing. These high temperatures are often outside of the reach of heating achieved by lasers in a reasonable amount of time.

As a second example, any adhesive that can withstand the manufacturing temperatures may be chosen to bond the carrier wafer to the thin wafer. After manufacturing has completed, the adhesive may be removed using a bulk chemical etch. Chemical use results in particle residue left on the thin wafer. These particles are problematic for packaging the thin wafer or stacking additional layers on top as in a stacked IC.

Thus, there is a need for a method of releasing the carrier wafer from the thin wafer without exposing the wafers to high temperatures or bulk chemical baths.

### BRIEF SUMMARY

According to one aspect of the disclosure, a semiconductor wafer includes a plurality of dies to be scored from the semiconductor wafer. The semiconductor wafer also includes a scribe-line between the plurality of dies. Each scribe-line includes a through silicon via.

According to another aspect of the disclosure, a method for transporting liquid through an active wafer having a scribe-line to a carrier wafer includes fabricating a through silicon via in the scribe-line of the active wafer. The method also includes applying the liquid to the active wafer, wherein the liquid is adapted to flow through the through silicon via.

According to yet another aspect of the disclosure, a method for facilitating scoring of dies on a wafer having a scribe-line and a plurality of dies including fabricating a through silicon via in the scribe-line of the wafer. The method also includes scoring the wafer.

According to a further aspect of the disclosure, a semiconductor wafer having a plurality of dies includes means for separating individual dies. The semiconductor wafer also includes means for flowing liquid through the semiconductor wafer contained in the means for separating individual dies.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a block diagram showing an exemplary wireless communication system in which an embodiment of the disclosure may be advantageously employed.

FIG. 2 is a top view illustrating a substrate having multiple dies, multiple scribe-lines, and multiple through silicon vias.

FIG. 3 is a cross-sectional view illustrating a substrate having multiple dies, multiple scribe-lines, and multiple through silicon vias.

FIG. 4 is a flow chart demonstrating one method in which an embodiment of the disclosure may be advantageously employed.

FIG. 5 is a block diagram illustrating an active wafer and carrier wafer before carrier mounting, according to an embodiment of the disclosure.

FIG. 6 is a block diagram illustrating an active wafer and carrier wafer after carrier mounting, according to an embodiment of the disclosure.

FIG. 7 is a block diagram illustrating an active wafer and carrier wafer after thinning of the active wafer, according to an embodiment of the disclosure.

FIG. 8 is a block diagram illustrating an active wafer and carrier wafer after other processes have completed on the active wafer, according to an embodiment of the disclosure.

FIG. 9 is a block diagram illustrating an active wafer and carrier wafer after adhesive release etch through vias, according to an embodiment of the disclosure.

### DETAILED DESCRIPTION

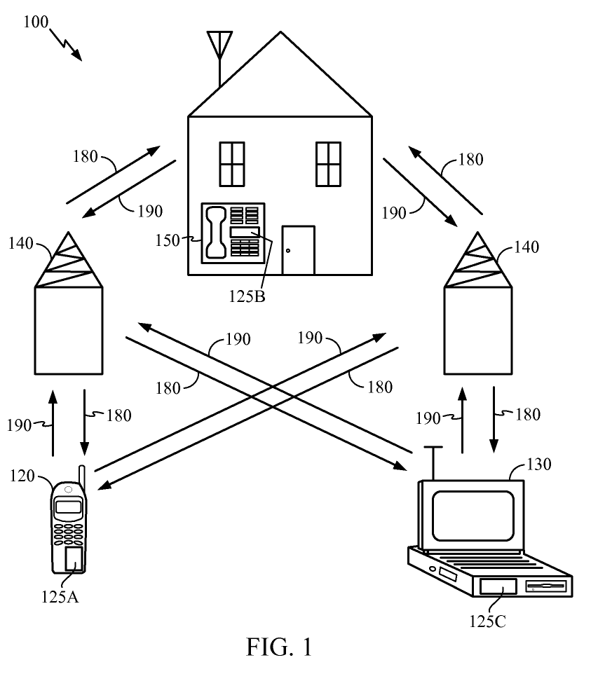

FIG. 1 is a block diagram showing an exemplary wireless communication system 100 in which an embodiment of the disclosure may be advantageously employed. For purposes of illustration, FIG. 1 shows three remote units 120, 130, and 150 and two base stations 140. It will be recognized that typical wireless communication systems may have many more remote units and base stations. Remote units 120, 130, and 150 include IC devices 125A, 125B and 125C, that include the circuitry disclosed here. It will be recognized that any device containing an IC may also include the circuitry disclosed here, including the base stations, switching devices, and network equipment. FIG. 1 shows forward link signals 180 from the base station 140 to the remote units 120, 130, and 150 and reverse link signals 190 from the remote units 120, 130, and 150 to base stations 140.

In FIG. 1, remote unit 120 is shown as a mobile telephone, remote unit 130 is shown as a portable computer, and remote unit 150 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 1 illustrates remote units according to the teachings of the disclosure, the disclosure is not limited to these exemplary illustrated units. The disclosure may be suitably employed in any device which includes integrated circuits, as described below.

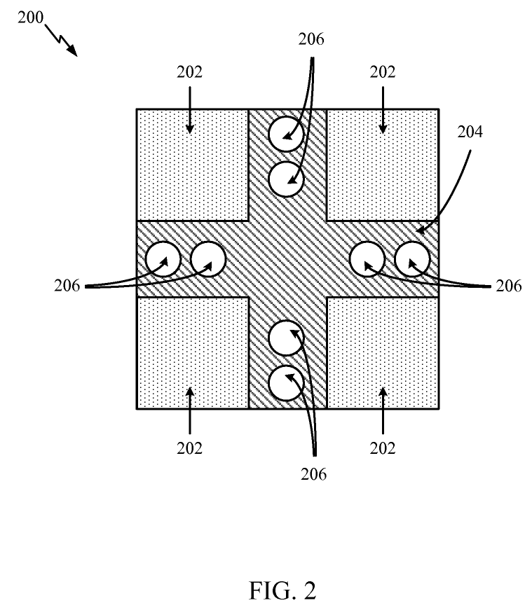

FIG. 2 is a top view illustrating a substrate having multiple dies, multiple scribe-lines, and multiple through silicon vias embedded in the scribe-lines. A wafer 200 includes dies 202 separated by scribe-lines 204. The dies 202 may be memory devices, microprocessors, or communications devices. Forming the scribe-lines 204, in one embodiment, is by processing including photolithography, deposition, patterning, and etching. The wafer 200 may be single crystal silicon according to one embodiment, but may be other materials including gallium arsenide. The dies 202 included on the wafer 200 may include microprocessors, memory, other circuitry, or a fraction of each. The scribe-lines 204 are sections of the wafer 200 that have been thinned to facilitate separation of the dies 202 by providing a path along which to score the wafer 200. Thus, the scribe-lines 204 may prevent damage to the dies 202 caused by errant scoring.

After all manufacturing processes have completed and the dies 202 are scored from the wafer 200, the dies 202 may be packaged as flip-chips or packaged through a variety of other techniques. Individually packaged dies are then sold as products.

According to an aspect of the disclosure, through silicon vias 206 are embedded in the scribe-lines 204. The through silicon vias 206 may be manufactured by via first or via last techniques that include laser drilling, plasma etching, or wet etching. In any case, the through silicon vias 206 may extend a fraction of or the entire depth of the wafer 200. The through silicon vias 206 may be used, later in manufacturing, to provide a channel for liquid solution from a front side of the wafer 200 to a back side of the wafer 200. The through silicon vias 206 may also be used to facilitate scoring of the wafer 200. Because portions of the wafer 200 are removed to form the through silicon vias 206, the saw or laser scoring the wafer 200 may engage the wafer 200 at higher feed rates improving throughput of the dicing process.

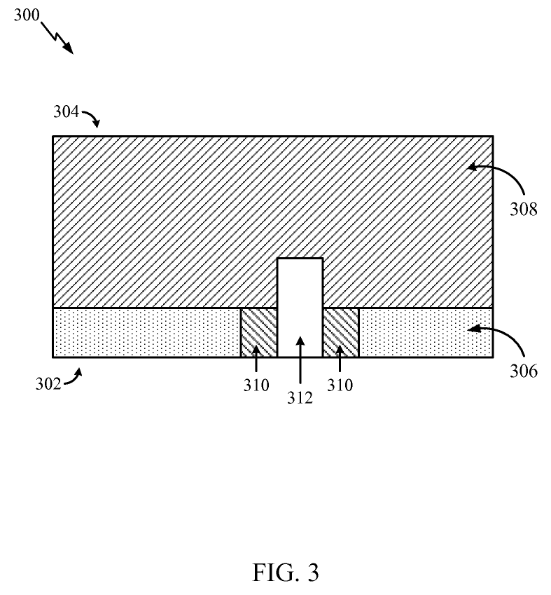

Referring now to FIG. 3, a cross-sectional view illustrating a substrate having multiple dies, multiple scribe-lines, and multiple through silicon vias is presented. A wafer 300 includes an active region 306 and a bulk region 308. Multiple dies may exist on the wafer 300 that are later separated into individual products. The wafer 300 has a front side 302 and a back side 304. A portion of the active region 306 is removed to form a scribe-line 310 on the front side 302. Removal is accomplished by etching a portion of the active region 306. According to one embodiment the scribe-line 310 may be 10-50 μm deep. The scribe-line 310 facilitates separating the active region 306 into individual dies by acting as a guide during scoring to prevent accidental damage to the dies.

Additionally, a portion of the active region 306 and the bulk region 308 are removed to form a through silicon via 312. According to one embodiment, the through silicon via 312 may be, 30-300 μm deep and used to deliver liquid solution from the front side 302 to the back side 304 when the wafer 300 is bonded to a carrier wafer (not shown). Thinning the bulk region 308 in later processing to expose the through silicon via 312 on the front side 302 and the back side 304 of the wafer 300 creates a channel for liquid solutions to flow from the front side 302 to the back side 304. According to another embodiment, the through silicon vias 312 may extend the depth of the wafer 300.

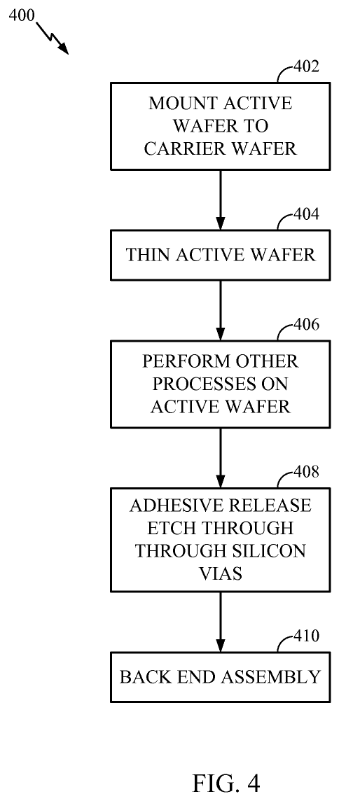

FIG. 4 is a flow chart demonstrating one method in which an embodiment of the disclosure may be advantageously employed. A process 400 is used to fabricate dies on active wafers that are thin wafers. As described above, thin wafers are extremely fragile and difficult to handle during manufacturing. As a result, the active wafers are mounted on carrier wafers that are much thicker and less fragile for a duration of the manufacturing process.

At block 402, an active wafer is mounted to a carrier wafer using adhesive. Continuing to block 404, the active wafer is thinned to a desired thickness. The active wafer may be thinned, for example, by grinding, chemical mechanical polishing (CMP) or bulk etch processes.

At block 406, other manufacturing processes may be performed on the active wafer as desired by the specific design for the active wafer. One such manufacturing process, for example, is dielectric deposition.

At block 408, an adhesive etching solution flows through the through silicon vias to reach the adhesive between the active wafer and the carrier wafer. The etching solution dissolves the adhesive allowing the active wafer to be released from the carrier wafer.

Continuing to block 410, back end assembly is performed on the active wafer or on individual dies scored from the active wafer. A general process for using the teachings of the disclosure has been outlined, but it should be recognized that design parameters may be modified according to the product design specifications.

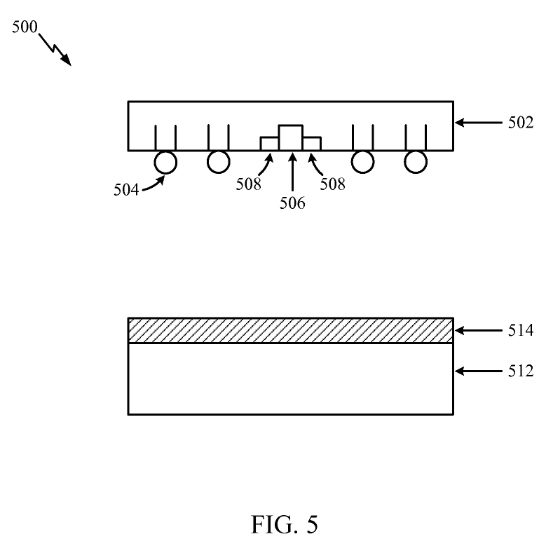

FIG. 5 is a block diagram illustrating an active wafer and a carrier wafer before carrier mounting. Before carrier mounting occurs, an active wafer 502 and a carrier wafer 512 are separate wafers as shown in a block diagram 500. The active wafer 502 includes a contact pad 504, a scribe-line 508, and a through silicon via 506. An adhesive 514 is placed on the carrier wafer 512.

The through silicon via 506 as shown does not extend the depth of the active wafer 502, but may extend the depth depending on the process chosen for manufacturing the through silicon via 506. In later processing, the active wafer 502 may be thinned to expose the through silicon via 506. Although only one scribe-line and one through silicon via are illustrated, there may be many more.

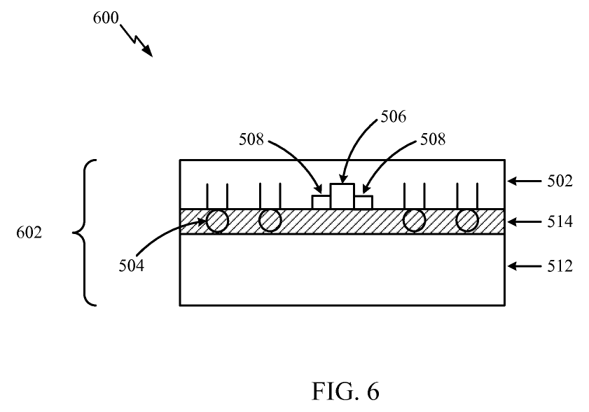

FIG. 6 is a block diagram illustrating an active wafer and carrier wafer after carrier mounting. After carrier mounting, the active wafer 502 is bonded to the carrier wafer 512 by the adhesive 514 to form a structure 602. The structure 602 has reduced the fragility of the active wafer 502 allowing it to withstand manufacturing processes that otherwise may damage the active wafer 502.

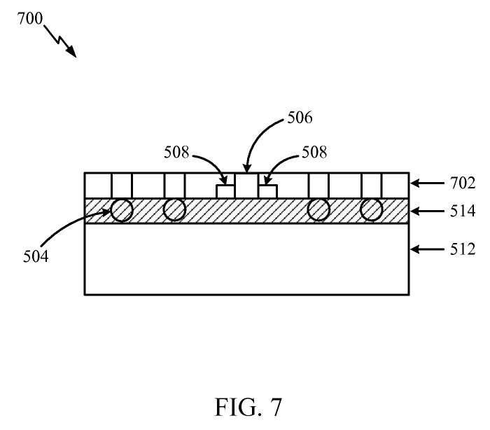

FIG. 7 is a block diagram illustrating an active wafer and carrier wafer after thinning of the active wafer. During one of many processes during

Additional manufacturing processes may be carried out on the active wafer 702 such as dielectric deposition. During these additional processes, the scribe-line 508 and the through silicon via 506 may be masked off.

After other manufacturing processes have completed, the adhesive 514 should be dissolved to detach the active wafer 702 from the carrier wafer 512. This is accomplished, according to one embodiment of the disclosure, by flowing etching solution through the through silicon via 506. The etching solution contacts and dissolves the adhesive 514.

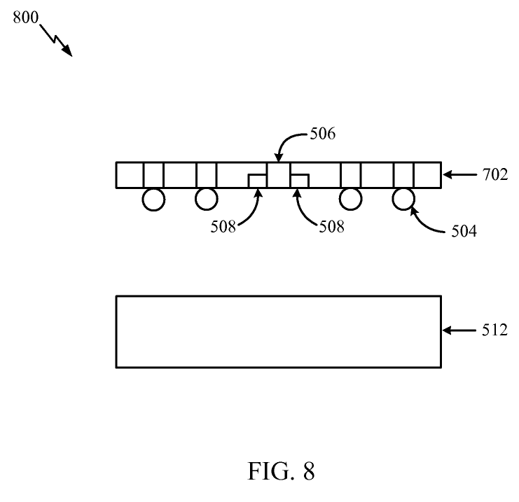

FIG. 8 is a block diagram illustrating an active wafer and carrier wafer after other processes have completed on the active wafer. After the adhesive 514 is dissolved, the active wafer 702 is separated from the carrier wafer 512. The active wafer 702 may be scored into individual dies.

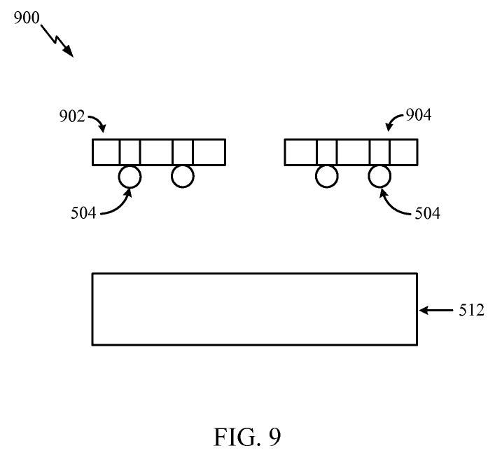

FIG. 9 is a block diagram illustrating an active wafer and carrier wafer after adhesive release etch through vias. The active wafer 702 is cut into a first die 902 and a second die 904. Although only two dies are shown, the active wafer 702 may be cut into many more dies.

The advantages of scribe-lines having through silicon vias embedded include easier carrier release by providing a direct path for adhesive etching solutions through the wafer. This reduces residue left on the wafer that may adversely affect future fabrication or packaging processes. Additionally, the scribe-lines are otherwise wasted space, and the through silicon vias do not reduce the area available for active circuitry. Further, the through silicon vias are produced through a well known manufacturing process, and therefore make use of existing techniques and recipes for processes. The through silicon vias also decrease the time and expense of scoring the wafer because part of the substrate has already been removed to form the through silicon vias. Using the embodiments described above, active wafers as thin as 30 μm or smaller may be used in stacked ICs without increasing the risk of damaging the active wafer.

Through silicon vias as disclosed here may be manufactured using a variety of known techniques including via first, via last, or a combination of techniques. In each technique separate processes are used, and one of ordinary skill in the art will be able to apply the techniques or processes to the present disclosure. Accordingly, the sizes of the through silicon vias and connected components may vary based on the technique and process chosen. The present disclosure is intended to embody all techniques and processes capable of manufacturing the through silicon vias.

Although the terminology “through silicon via” includes the word silicon, it is noted that through silicon vias are not necessarily constructed in silicon. Rather, the material can be any device substrate material.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor wafer, comprising:
a plurality of dies to be scored from the semiconductor wafer; and
a scribe-line between the plurality of dies, each scribe-line comprising a through silicon via.

2. The semiconductor wafer of claim 1, in which the scribe-line is 10 to 50 micrometers deep.

3. The semiconductor wafer of claim 1, in which the through silicon via is 30 to 300 micrometers deep.

4. The semiconductor wafer of claim 1, in which the through silicon via extends the entire depth of the wafer.

5. The semiconductor wafer of claim 1, in which at least one of the plurality of dies comprises at least a portion of a microprocessor.

6. The semiconductor wafer of claim 1, in which at least one of the plurality of dies comprises at least a portion of a communications device.

7. The semiconductor wafer of claim 1, in which the plurality of dies are flip-chips.

8. A method for transporting a liquid through an active wafer having a scribe-line to a carrier wafer, the method comprising:
fabricating a through silicon via in the scribe-line of the active wafer, wherein the through silicon via is adapted to allow the liquid to flow through the through silicon via; and
applying the liquid to the active wafer.

9. The method of claim 8, in which applying the liquid comprises applying an etching solution to the active wafer.

10. The method of claim 9, further comprising dissolving an adhesive binding the carrier wafer to the active wafer to release the carrier wafer from the active wafer.

11. The method of claim 8, further comprising thinning the active wafer to expose the through silicon vias before applying the liquid solution.

12. The method of claim 11, further comprising depositing a dielectric on the active wafer.

13. A method for facilitating scoring of dies on a wafer having a scribe-line and a plurality of dies, the method comprising:
fabricating a through silicon via in the scribe-line of the wafer; and
scoring the wafer.

14. The method of claim 13, in which scoring the wafer comprises cutting through the scribe-line using a saw.

15. The method of claim 14, in which scoring the wafer comprises cutting through the scribe-line using a laser.

16. A semiconductor wafer having a plurality of dies, the semiconductor wafer comprising:
means for separating individual dies; and
means for flowing liquid through the semiconductor wafer contained in the means for separating individual dies.

17. The semiconductor wafer of claim 16, in which means for flowing liquid comprises means for flowing etching solution through the semiconductor wafer.

18. The semiconductor wafer of claim 17, in which means for flowing liquid comprise a through silicon via.
